(19) United States
(12) Patent Application Publication
(10) Pub. No.: US 2008/0237740 A1
(43) Pub. Date: Oct. 2, 2008

(54) SEMICONDUCTOR DEVICE AND THE MANUFACTURING METHOD THEREOF

(75) Inventors: Jung-Ching Chen, Hsinchu City (TW); Chun-Ching Yu, Taoyuan County (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/693,437

(22) Filed: Mar. 29, 2007

(51) Int. Cl. H01L 27/088; H01L 21/77

(52) U.S. Cl. 257/391; 438/275; 257/E27.06; 257/E21.598

(57) ABSTRACT

A method of manufacturing a semiconductor device is provided. First, a substrate is provided. The substrate includes a high-voltage device region and a low-voltage device region. The high-voltage device region has a source/drain predetermined region, a pick-up predetermined region and a channel predetermined region. A first dielectric layer is formed on the substrate. Then, the first dielectric layer in the low-voltage device region is removed along with the first dielectric layer in the source/drain predetermined region and the pick-up predetermined region. Afterwards, a second dielectric layer is formed in the low-voltage device region. The thickness of the second dielectric layer is smaller than the thickness of the first dielectric layer. Then, gates are formed in the channel predetermined region and the low-voltage device region respectively. Next, a source/drain region is formed in the substrate of the source/drain predetermined region.

### BACKGROUND OF THE INVENTION

1. Field of the Invention

The present invention relates to an integrated circuit structure and a method of manufacturing the same, and more particularly, to a semiconductor device and a manufacturing method thereof.

2. Description of Related Art

With the rapid development in the technologies of the integrated circuit, the production and the design of electronic devices with high efficiency, high integration, low cost, light weight and compact size have been the primary targets of the industry. At present, most semiconductor manufacturers need to fabricate devices with a variety of functions on the same chip in order to reach the above targets.

Integrating high-voltage devices with low-voltage devices on the same chip is one of the methods which meet the above requirements, such as system on chip (SOC). However, in order to withstand a higher breakdown voltage, the thickness of the gate oxide layer in the high-voltage device is usually remarkably greater than the thickness of the gate oxide layer in the low-voltage device. With this particular requirement, various problems arise in the process of integrating the high-voltage device with the low-voltage device.

In order to meet the requirements of different thicknesses of the gate oxide layers, the conventional method is forming a whole layer of high-voltage gate oxide layer first with a thickness of >300 angstroms. Afterwards, the portion of the high-voltage gate oxide layer in the low-voltage device region is removed by a lithography process and an etching process. Then, a low-voltage gate oxide layer of the low-voltage device region is formed. Moreover, since the high-voltage gate oxide layer also covers the region within the high-voltage device region reserved for performing an ion implantation process, such as a source/drain region and a well pick-up doped region, in order to facilitate control of the concentration, depth and profile of the ion implantation, another lithography process and an etching process is usually applied to remove the high-voltage gate oxide layer in these regions. This method requires a great number of photomasks and it not only prolongs the whole manufacturing process but increases the complexity and the production cost of the manufacturing process as well.

### SUMMARY OF THE INVENTION

In view of the above, the present invention provides a manufacturing method of a semiconductor device, wherein one manufacturing process removes both a dielectric layer in the low-voltage device region and a dielectric layer in the regions reserved for forming a source/drain region and a well pick-up doped region in the high-voltage device region.

The invention provides a semiconductor device, and a dielectric layer disposed over a substrate in the region reserved for forming a doped region within the high-voltage device region is approximately the same as a gate dielectric layer in the low-voltage device region, which in turn facilitates a subsequent dopant implantation process.

The invention provides a manufacturing method of a semiconductor device. First, a substrate is provided. The substrate includes a high-voltage device region and a low-voltage device region. The high-voltage device region has a source/drain predetermined region, a pick-up predetermined region and a channel predetermined region. A first dielectric layer is formed on the substrate. Then, the first dielectric layer in the low-voltage device region is removed when the first dielectric layer in the source/drain predetermined region and the pick-up predetermined region is also removed as well. Afterwards, a second dielectric layer is formed at least in the low-voltage device region. The thickness of the second dielectric layer is smaller than the thickness of the first dielectric layer. Then, gates are formed in the channel predetermined region and the low-voltage device region respectively. Next, a source/drain region is formed in the substrate of the source/drain predetermined region.

In one embodiment of the invention, the manufacturing method of the semiconductor device further includes forming a second dielectric layer over the substrate in the source/drain predetermined region and the pick-up predetermined region.

According to one embodiment of the invention, in the manufacturing method of the semiconductor device, the method of forming the second dielectric layer includes a thermal oxidation process.

According to one embodiment of the invention, in the manufacturing method of the semiconductor device, the first dielectric layer of the low-voltage device region is removed along with the first dielectric layer in the source/drain predetermined region and the pick-up predetermined region. The first dielectric layers may be removed by first forming a patterned photoresist layer on the first dielectric layer and exposing the first dielectric layer in the low-voltage device region, the source/drain predetermined region and the pick-up predetermined region. Next, the exposed first dielectric layer and the patterned photoresist layer are also further removed.

According to one embodiment of the invention, the manufacturing method of the semiconductor device further includes performing an ion implantation process before removing the exposed first dielectric layer.

According to one embodiment of the invention, the manufacturing method of the semiconductor device includes forming a plurality of isolation structures to isolate the high-voltage device region from the low-voltage device region before forming the first dielectric layer.

According to one embodiment of the invention, in the manufacturing method of the semiconductor device, the high-voltage device region includes an N-type device region and a P-type device region.

According to one embodiment of the invention, in the manufacturing method of the semiconductor device, the isolation structures are a plurality of shallow trench isolation structures isolating the N-type device region, the P-type device region and the low-voltage device region.

According to one embodiment of the invention, in the manufacturing method of the semiconductor device, the isolation structures are a plurality of field oxidation layers that isolate the N-type device region, the P-type device region and the low-voltage device region. The field oxidation layers further isolate the source/drain predetermined region, the pick-up predetermined region and the channel predetermined region.

According to one embodiment of the invention, in the manufacturing method of the semiconductor device, the method of forming the first dielectric layer includes a thermal oxidation process.

According to one embodiment of the invention, in the manufacturing method of the semiconductor device, the material of the gate includes doped polysilicon.

The present invention provides a semiconductor device including a substrate, a high-voltage transistor, a high-voltage well region, a well pick-up doped region, a low-voltage transistor and a dielectric layer. The substrate has a high-voltage device region and a low-voltage device region. The high-voltage transistor is disposed over the substrate in the high-voltage device region. The high-voltage transistor includes a high-voltage gate dielectric layer and a gate stacked up from the bottom, and a source/drain region disposed on the two sides of the gate. The high-voltage well region is disposed in the substrate of the high-voltage device region. The well pick-up doped region is disposed in the substrate of the high-voltage well region. The low-voltage transistor is disposed over the substrate in the low-voltage device region, and the low-voltage transistor includes a low-voltage gate dielectric layer and a gate stacked up from the bottom. The dielectric layer is disposed over the substrate in the source/drain region and the well, pick-up doped region. The thickness of the low-voltage gate dielectric layer is smaller than the thickness of the high-voltage gate dielectric layer, and the thicknesses of the dielectric layer and the low-voltage gate dielectric layer are approximately the same.

According to one embodiment of the invention, in the semiconductor device, the dielectric layer and the low-voltage gate dielectric layer are formed in the same step.

According to one embodiment of the invention, in the semiconductor device, the method of forming the dielectric layer and the low-voltage gate dielectric layer includes a thermal oxidation process.

According to one embodiment of the invention, in the semiconductor device, a plurality of isolation structures are disposed in the substrate to isolate the high-voltage device region from the low-voltage device region.

According to one embodiment of the invention, in the semiconductor device, the high-voltage device region includes an N-type device region and a P-type device region.

According to one embodiment of the invention, in the semiconductor device, the isolation structures are a plurality of shallow trench isolation structures isolating the N-type device region, the P-type device region and the low-voltage device region.

According to one embodiment of the invention, in the semiconductor device, the isolation structures are a plurality of field oxidation layers isolating the N-type device region, the P-type device region and the low-voltage device region. The field oxidation layers further isolate the gate, the source/drain region, and the well pick-up doped region.

The semiconductor device and the manufacturing method thereof disclosed in the present invention can reduce the number of photomask procedures required during the whole manufacturing process. One photomask procedure removes both the dielectric layers in the low-voltage device region and in portions of the high-voltage device region. There is no need to apply another photomask procedure to remove portions of the dielectric layer in the high-voltage device region before forming a doped region.

In order to the make the aforementioned and other objects, features and advantages of the present invention more comprehensible, preferred embodiments accompanied with figures are described in detail below.

### BRIEF DESCRIPTION OF THE DRAWINGS

FIGS. 1A to 1D are cross-sectional views illustrating a manufacturing process of a semiconductor device according to one embodiment of the present invention.

### DESCRIPTION OF EMBODIMENTS

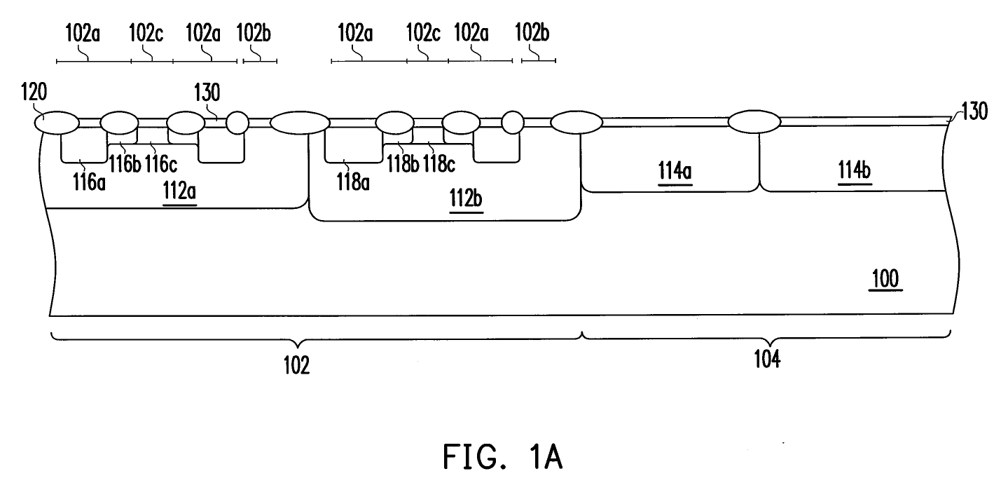

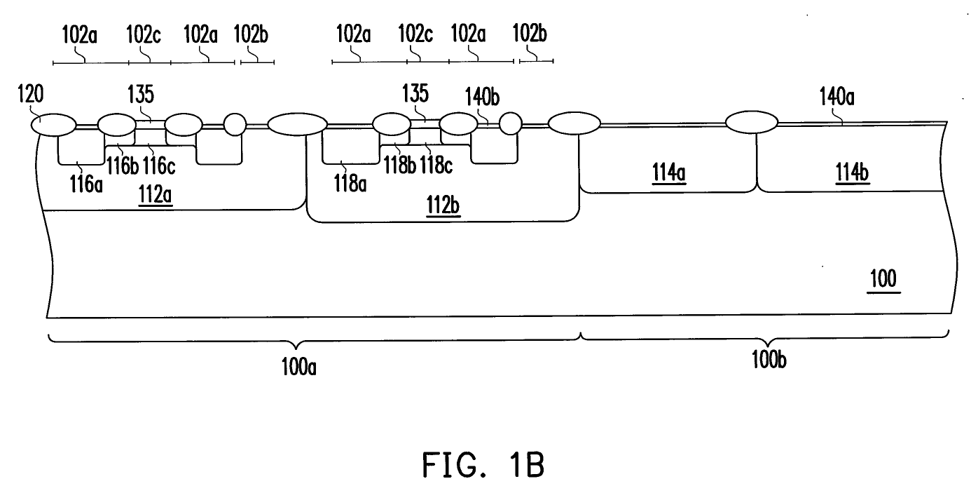

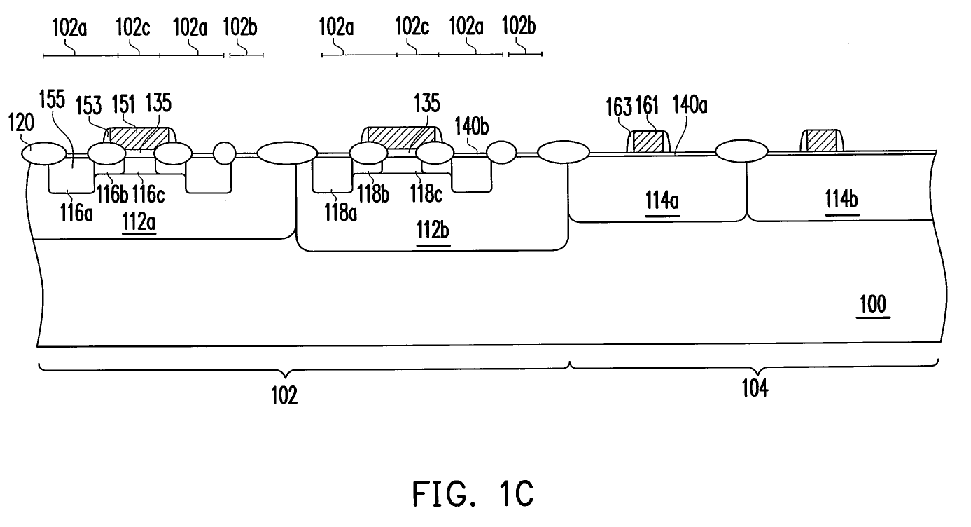

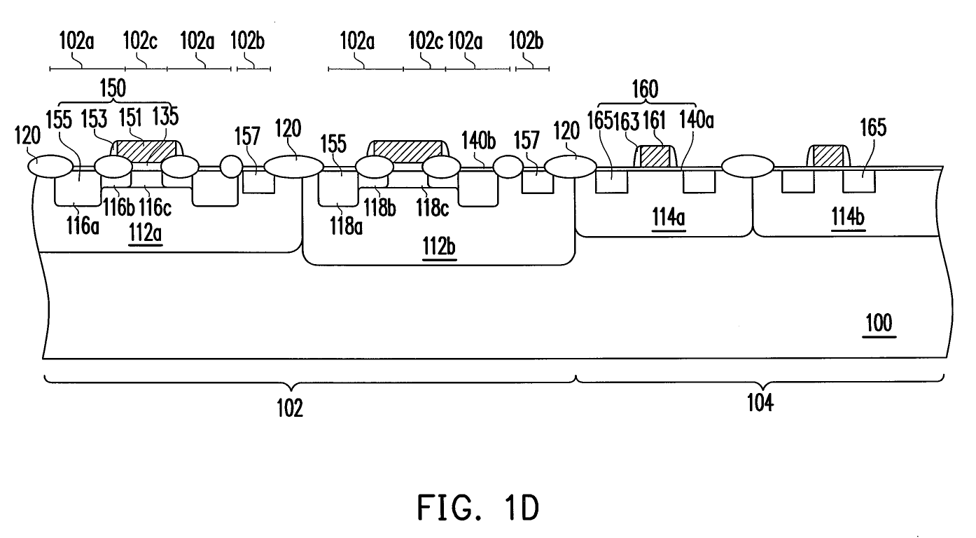

FIGS. 1A to 1D schematically illustrate a manufacturing method of a semiconductor device according to one embodiment of the invention.

Referring to FIG. 1A, the manufacturing method includes that first a substrate 100 is provided. The substrate 100 includes a high-voltage device region 102 and a low-voltage device region 104. The high-voltage device region 102 has a source/drain predetermined region 102a, a pick-up predetermined region 102b and a channel predetermined region 102c. The substrate 100 may be a silicon substrate. A high-voltage P well 112a and a high-voltage N well 112b may have been formed in the substrate 100 of the high-voltage device region 102 so as to be used as the well regions in the N-type transistor and the P-type transistor. The dopant of the high-voltage P well 112a may be a P-type dopant such as boron or boron difluoride (BF₂). The dopant of the high-voltage N well 112b may be an N-type dopant such as arsenic ion or phosphorous ion. A low-voltage P well 114a and a low-voltage N well 114b may also have been formed in the substrate 100 of the low-voltage device region 104.

In one embodiment, a plurality of isolation structures 120 is formed in the substrate 100 to isolate the high-voltage device region 102 and the low-voltage device region 104. The isolation structures 120 are also used to isolate the high-voltage P well 112a from the high-voltage N well 112b in the high-voltage device region 102. The isolation structures 120 may be shallow trench isolation structures or field oxidation layers. The material may be an isolating material such as silicon oxide. Given that the forming method of the isolation structures is well-known to people skilled in the art, it is not to be reiterated herein.

In the present embodiment, the isolation structures 120 may be field oxidation layers. They are not only used to isolate adjacent transistors but also separate from one another the source/drain predetermined region 102a, the pick-up predetermined region 102b and the channel predetermined region 102c of the high-voltage device region 102.

Moreover, since the transistors in the high-voltage device region 102 have to withstand larger voltages, in order to avoid electric leakage or abnormal conductivity caused by high-voltages, an N-type grade region 116a and an N-type drift region 116b are further formed in the source/drain predetermined region 102a of the high-voltage P well 112a, and an N-type channel doped region 116c is formed in the channel predetermined region 102c of the high-voltage P well 112a. Further, a P-type grade region 118a and a P-type drift region 118b are formed in the source/drain predetermined region 102a of the high-voltage N well 112b, and a P-type channel doped region 118c is formed in the channel predetermined region 102c of the high-voltage N well 112b.

Still referring to FIG. 1A, a dielectric layer 130 is formed over the substrate 100. The material of the dielectric layer 130 may be silicon oxide, and the method of forming the dielectric layer 130 may be a thermal oxidation process or a chemical vapor deposition process (CVD).

Referring to FIG. 1B, next, the dielectric layer 130 in the low-voltage device region 104 is removed along with the dielectric layer 130 in the source/drain predetermined region 102a and the pick-up predetermined region 102b so as to define a high-voltage gate dielectric layer 135 over the substrate 100 in the channel predetermined region 102c. The method of removing the dielectric layer 130 in these regions may include that a patterned mask layer (not shown) is first formed over the substrate 100 and exposes the low-voltage device region 104, the source/drain predetermined region 102a and the pick-up predetermined region 102b. Afterwards, a wet etching process or a dry etching process is used to remove the exposed dielectric layer 130. Then, the patterned photoresist layer is removed by a wet photoresist stripping process or a dry photoresist stripping process.

Referring to FIG. 1B again, a dielectric layer 140a is formed at least over the low-voltage device region 104. The dielectric layer 140a is used as a low-voltage gate dielectric layer of the low-voltage device. The thickness of the dielectric layer 140a is smaller than the thickness of the dielectric layer 130. In one embodiment, the thickness of the dielectric layer 140a may be 40˜100 angstroms. Taking a low-voltage device with a gate voltage around 3 volts as an example, the more common thickness of a dielectric layer may be 65 angstroms. The material of the dielectric layer 140a may be silicon oxide, and the dielectric layer 140a may be formed by a thermal oxidation process. Since the dielectric layer 130 in the source/drain predetermined region 102a and the pick-up predetermined region 102b has already been removed in the last step and exposes the substrate 100 of these regions, during the thermal oxidation process, a dielectric layer 140b is also formed over the substrate 100 of the source/drain predetermined region 102a and the pick-up predetermined region 102b.

Referring to FIG. 1C, then, a gate 151 and a gate 161 are respectively formed over the substrate 100 of the channel predetermined region 102c and the low-voltage device region 104. The material of the gates 151 and 161 may be doped polysilicon. The method of forming the gates may include that first a conformal doped polysilicon layer (not shown) is formed and then a lithography process and an etching process are performed to form the gates. The method of forming the doped polysilicon layer may include performing a chemical vapor deposition process to form an undoped polysilicon layer and performing an ion implantation process thereafter. Alternatively, the doped polysilicon layer may be formed by a chemical vapor deposition process with in-situ doping.

After forming the gates 151 and 161, spacers 153 and 163 may be further formed on the side walls of the gates 151 and 161. The material of the spacers 153 and 163 may be dielectric materials such as silicon oxide. The method of forming the spacers may include first forming a spacer material layer (not shown) over the substrate 100. Next, an isotropic etching process is performed to remove a portion of the spacer material layer to form the spacers 153 and 163 of the side walls of the gates. In order to increase the conductivity, metal silicide (not shown), such as tungsten silicide, may be formed on the gates 151 and 161.

Referring to FIG. 1D, afterwards, a dopant implantation process is performed to form a source/drain region 155 and a well pick-up doped region 157 over the substrate 100 in the source/drain predetermined region 102a. The position of the source/drain region 155 may at least partially overlap with the positions of the previous grade regions (116a and 118a). Transistors of different conductive types are formed over the substrate 100 in the high-voltage device region 102. N-type transistors are formed on the high-voltage P well 112a and P-type transistors are formed on the high-voltage N well 112b.

In one embodiment, a P-type ion implantation process is first performed to form a P-type source/drain region 155 in the high-voltage N well 112b and a P-type well pick-up doped region 157 is formed in the high-voltage P well 112a. Certainly, a P-type source/drain region 165 may also be formed in the low-voltage N well 114b.

Then, an N-type ion implantation process is performed to form an N-type source/drain region 155 in the high-voltage P well 112a and an N-type well pick-up doped region 157 is formed in the high-voltage N well 112b. Similarly, an N-type source/drain region 165 may also be formed in the low-voltage P well 114a. Given that the subsequent steps of forming contacts and well pick-ups are well-known to people skilled in the art, they are not to be reiterated herein.

The dielectric layer 130 originally formed in the source/drain predetermined region 102a and the pick-up predetermined region 102b is removed simultaneously with the dielectric layer 130 in the low-voltage device region 104. Therefore, before performing the aforementioned ion implantation process, there is no need to apply another photomask procedure to open these regions. The concentration and the profile of the formed doped regions can also be well controlled. In other words, the manufacturing method of the semiconductor device in the present embodiment can save one photomask procedure and thus simplify the whole manufacturing process and lower the production cost. Further, the manufacturing method also helps control the subsequent dopant implantation process.

A semiconductor device of one embodiment of the invention is described in the following.

Referring to FIG. 1D, the semiconductor device includes a substrate 100, a high-voltage well region, a high-voltage transistor 150, a well pick-up doped region 157, a low-voltage transistor 160 and a dielectric layer 140b.

The substrate 100 has a high-voltage device region 102 and a low-voltage device region 104. The high-voltage well region is disposed in the substrate 100 of the high-voltage device region 102. In one embodiment, the high-voltage well region may include a high-voltage P well 112a and a high-voltage N well 112b disposed over the high-voltage device region 102 to operate with high-voltage transistors 150 of different conductive types.

The high-voltage transistor 150 includes a high-voltage gate dielectric layer 135 and a gate 151 stacked up from the bottom and a source/drain 155 disposed on the two sides of the gate 151 in the high-voltage well region. The material of the high-voltage gate dielectric layer 135 may be silicon oxide. The thickness of the high-voltage gate dielectric layer 135 may be larger than 500 angstroms, such as 700˜900 angstroms, depending on the requirements of an actual device. The material of the gate 151 may be doped polysilicon, metal or metal silicide. The two sides of the gate 151 may be further disposed the spacers 153. The material of the spacers 153 may be dielectric materials such as silicon oxide.

The source/drain region 155 may be an N-type doped region or a P-type doped region. The source/drain region 155 in the high-voltage P well 112a is an N-type doped region. The N-type doped region may have dopants with a concentration of 1×10¹⁵/cm³ arsenic ions or phosphorous ions and the high-voltage transistor 150 disposed over the high-voltage P well 112a is an N-type transistor. The source/drain region 155 in the high-voltage N well 112b is a P-type doped region. The P-type doped region may have dopants with a concentration of 1×10¹⁵/cm³ boron ions and the high-voltage transistor 150 disposed over the high-voltage N well 112b is a P-type transistor.

The well pick-up doped region 157 is further disposed in the high-voltage well region (the high-voltage P well 112a and the high-voltage N well 112b) and is classified as a P-type or an N-type well pick-up doped region 157 according to different conductive types of the well regions.

A low-voltage well region (a low-voltage P well 114a and a low-voltage N well 114b) may be disposed in the substrate 100 of the low-voltage device region 104. A low-voltage transistor 160 is disposed over the substrate 100 in the low-voltage well region. The low-voltage transistor 160 includes a low-voltage gate dielectric layer 140a and a gate 161 stacked up from the bottom and a source/drain region 165 disposed on the two sides of the gate 163 in the low-voltage well region. The thickness of the low-voltage gate dielectric layer 140a is smaller than the thickness of the high-voltage gate dielectric layer 135 and may be 40-100 angstroms, such as 65 angstroms.

A dielectric layer 140b is disposed over the substrate 100 in the source/drain region 155 and the well pick-up doped region 157 of the high-voltage device region 102. The thicknesses of the dielectric layer 140b and the low-voltage dielectric layer 140a are approximately the same. In one embodiment, the dielectric layer 140b and the low-voltage gate dielectric layer 140a may be formed in the same step.

Isolation structures 120 are disposed between the high-voltage device region 102 and the low-voltage device region 104. The isolation structures 120 may be field oxidation layers or shallow trench isolation structures. The material thereof may be silicon oxide. The isolation structures 120 may be further disposed in the substrate 100 of the high-voltage device region 102 to isolate the high-voltage P well 112a from the high-voltage N well 112b. In one embodiment, the isolation structures 120 such as field oxidation layers may be further disposed among the source/drain region 155, the gate 151 and the well pick-up doped region 157 in the high-voltage device region 102.

In summary, the foregoing embodiments use one photomask procedure to remove the dielectric layer 130 in the source/drain predetermined region 102a and the pick-up predetermined region 102b of the high-voltage device region 102 and in the low-voltage device region 104. Hence, before performing the subsequent step of forming doped regions (the source/drain region 155 and the well pick-up doped region 157), there is no need to apply another photomask procedure to remove the dielectric layer 130 in the source/drain predetermined region 102a and the pick-up predetermined region 102b of the high-voltage device region 102. The step of a dopant implantation process can proceed directly. Thus, not only is the production cost lowered, the manufacturing process shortened, the profile and the concentration of the dopants in the subsequent step can also be better controlled.

Although the present invention has been disclosed above by the embodiments, they are not intended to limit the present invention. Anybody ordinarily skilled in the art can make some modifications and alterations without departing from the spirit and scope of the present invention. Therefore, the protecting range of the present invention falls in the appended claims.

What is claimed is:

1. A manufacturing method of a semiconductor device, comprising:
providing a substrate, the substrate comprising a high-voltage device region and a low-voltage device region, wherein the high-voltage device region comprises a source/drain predetermined region, a pick-up predetermined region and a channel predetermined region;
forming a first dielectric layer over the substrate;
removing the first dielectric layer in the low-voltage device region simultaneously as the first dielectric layer in the source/drain predetermined region and the pick-up predetermined region is removed;
forming a second dielectric layer at least in the low-voltage device region, wherein the thickness of the second dielectric layer is smaller than the thickness of the first dielectric layer;
forming a gate respectively in the channel predetermined region and the low-voltage device region; and
forming a source/drain region in the substrate of the source/drain predetermined region.

2. The manufacturing method of the semiconductor device of claim 1, further comprising forming a second dielectric layer over the substrate in the source/drain predetermined region and the pick-up predetermined region.

3. The manufacturing method of the semiconductor device of claim 1, wherein the method of forming the second dielectric layer comprises performing a thermal oxidation process.

4. The manufacturing method of the semiconductor device of claim 1, wherein removing simultaneously the first dielectric layer in the low-voltage device region, the source/drain predetermined region and the pick-up predetermined region comprises:
forming a patterned photoresist layer on the first dielectric layer and exposing the first dielectric layer in the low-voltage device region, the source/drain predetermined region and the pick-up predetermined region;
removing the exposed first dielectric layer; and
removing the patterned photoresist layer.

5. The manufacturing method of the semiconductor device of claim 1, further comprising performing an ion implantation process before removing the exposed first dielectric layer.

6. The manufacturing method of the semiconductor device of claim 1, wherein before forming the first dielectric layer, a plurality of isolation structures is formed over the substrate to isolate the high-voltage device region from the low-voltage device region.

7. The manufacturing method of the semiconductor device of claim 6, wherein the high-voltage device region comprises an N-type device region and a P-type device region.

8. The manufacturing method of the semiconductor device of claim 7, wherein the isolation structures are a plurality of shallow trench isolation structures isolating the N-type device region, the P-type device region and the low-voltage device region.

9. The manufacturing method of the semiconductor device of claim 7, wherein the isolation structures are a plurality of field oxidation layers isolating the N-type device region, the P-type device region and the low-voltage device region, the field oxidation layers further isolating the source/drain predetermined region, the pick-up predetermined region and the channel predetermined region.

10. The manufacturing method of the semiconductor device of claim 1, wherein the method of forming the first dielectric layer comprises performing a thermal oxidation process.

11. A semiconductor device, comprising:
a substrate, the substrate comprising a high-voltage device region and a low-voltage device region;
a high-voltage well region, disposed in the substrate of the high-voltage device region;
a high-voltage transistor, disposed over the substrate in the high-voltage well region, the high-voltage transistor comprising a high-voltage gate dielectric layer and a gate stacked up from the bottom, and a source/drain region disposed on the two sides of the gate in the high-voltage well region;
a well pick-up doped region, disposed in the substrate of the high-voltage well region;
a low-voltage transistor, disposed over the substrate in the low-voltage device region, the low-voltage transistor comprising at least a low-voltage gate dielectric layer; and
a dielectric layer, disposed over the substrate in the source/drain region and the well pick-up doped region,
wherein the thickness of the low-voltage gate dielectric layer is smaller than the thickness of the high-voltage gate dielectric layer, and the thicknesses of the dielectric layer and the low-voltage gate dielectric layer are approximately the same.

12. The semiconductor device of claim 11, wherein the dielectric layer and the low-voltage gate dielectric layer are formed in the same step.

13. The semiconductor device of claim 11, wherein the method of forming the dielectric layer and the low-voltage gate dielectric layer comprises performing a thermal oxidation process.

14. The semiconductor device of claim 11, wherein a plurality of isolation structures is disposed in the substrate to isolate the high-voltage device region from the low-voltage device region.

15. The semiconductor device of claim 14, wherein the high-voltage device region comprises an N-type device region and a P-type device region.

16. The semiconductor device of claim 15, wherein the isolation structures are a plurality of shallow trench isolation structures isolating the N-type device region, the P-type device region and the low-voltage device region.

17. The semiconductor device of claim 15, wherein the isolation structures are a plurality of field oxidation layers isolating the N-type device region, the P-type device region and the low-voltage device region, the field oxidation layers further isolating the gate, the source/drain region and the well pick-up doped region.
